(19) United States
(12) Patent Application Publication
(10) Pub. No.: US 2021/0257488 A1
(43) Pub. Date: Aug. 19, 2021

(54) EEPROM DEVICE WITH BOTTOM GATE STRUCTURE

(71) Applicant: QUALCOMM Incorporated, San Diego, CA (US)

(72) Inventors: Jean RICHAUD, AIX EN PROVENCE (FR); George Pete IMTHURN, San Diego, CA (US)

(21) Appl. No.: 16/792,384

(22) Filed: Feb. 17, 2020

(51) Int. Cl. H01L 29/788; H01L 27/11521; H01L 29/49; H01L 29/423; H01L 29/66

(52) U.S. Cl. CPC H01L 29/788; H01L 27/11521; H01L 29/66825; H01L 29/42336; H01L 29/495

(57) ABSTRACT

Certain aspects of the present disclosure generally relate to electrically erasable programmable read-only memory (EEPROM) device comprising at least one EEPROM cell structure. The EEPROM device generally includes a first active region, a second active region, a channel region disposed between the first active region and the second active region, a floating gate structure disposed above the channel region and separated from the channel region by a first dielectric layer, a control gate structure disposed above the floating gate structure and separated from the floating gate structure by a second dielectric layer, and a bottom gate structure disposed below the channel region.

### TECHNICAL FIELD

Certain aspects of the present disclosure generally relate to electronic components and, more particularly, to an electrically erasable programmable read-only memory (EEPROM) device including a bottom gate structure.

### BACKGROUND

Electrically erasable programmable read-only memories, EEPROMs, are a type of metal-oxide-semiconductor (MOS) transistor storage device used in applications where there is a need for changing programming or recording data in a digital circuit. These devices, termed non-volatile memories, retain their storage state after power is removed, unlike memory devices known as static memory (SRAM) or dynamic memory (DRAM) which immediately lose their storage state when power is disconnected. EEPROMs are characterized by a “floating gate” onto which electrical charge may be injected by a phenomenon known as “tunneling.”

In such circuits, a relatively high voltage is used to create a high electric field between the floating gate and a charge supply region, such as the drain or a region associated with the drain. The high electric field allows electrons to jump or tunnel through a very thin insulation material separating the floating gate from the charge supply region without damage to the insulation separating the two regions, a phenomenon known as Fowler-Nordheim tunneling. Similarly, by application of an opposite high voltage, charge may be removed from the floating gate, discharging the device.

Charge storage on the floating gate may be indicative of a digital signal (e.g., a one or zero) and may be read by observing the threshold voltage at which the transistor containing the floating gate begins to conduct. A first threshold voltage indicates a positive charge storage on the floating gate, while a second threshold voltage indicates a negative charge storage.

### SUMMARY

Certain aspects of the present disclosure generally relate to an electrically erasable programmable read-only memory (EEPROM) device comprising a bottom gate structure. The bottom gate structure may be biased to enhance hot carrier injection of electric charge into a floating gate structure.

Certain aspects of the present disclosure are generally directed to an electrically erasable programmable read-only memory (EEPROM) device comprising at least one EEPROM cell structure. The EEPROM device generally includes a first active region, a second active region, a channel region disposed between the first active region and the second active region, a floating gate structure disposed above the channel region and separated from the channel region by a first dielectric layer, a control gate structure disposed above the floating gate structure and separated from the floating gate structure by a second dielectric layer, and a bottom gate structure disposed below the channel region.

Certain aspects of the present disclosure are generally directed to a method of fabricating an electrically erasable programmable read-only memory (EEPROM) device comprising at least one EEPROM cell structure. The method generally includes forming a channel region, forming a first active region and a second active region, such that the channel region is disposed between the first active region and the second active region, forming a first dielectric layer disposed above the channel region, forming a floating gate structure disposed above the first dielectric layer, forming a second dielectric layer disposed above the floating gate structure, forming a control gate structure disposed above the second dielectric layer, and forming a bottom gate structure disposed below the channel region.

Certain aspects of the present disclosure are generally directed to a method of operating an electrically erasable programmable read-only memory (EEPROM) cell structure. The method generally comprises applying a bias voltage to a bottom gate structure of the EEPROM cell structure, wherein the EEPROM cell structure further comprises: a first active region, a second active region, a channel region disposed between the first active region and the second active region, a floating gate structure disposed above the channel region and separated from the channel region by a first dielectric layer, and a control gate structure disposed above the floating gate structure and separated from the floating gate structure by a second dielectric layer, wherein the bottom gate structure is disposed below the channel region, and while applying the bias voltage, applying a pulsed voltage to the second active region.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIGS. 1A and 1B illustrate a cross-sectional frontal view and top view, respectively, of an electrically erasable programmable read-only memory (EEPROM) cell structure, in accordance with certain aspects presented herein.

FIG. 2 is a flow diagram illustrating example operations for fabricating an EEPROM device comprising at least one EEPROM cell structure, in accordance with certain aspects of the present disclosure.

FIG. 3 is a flow diagram illustrating example operations for operating an EEPROM cell structure, in accordance with certain aspects of the present disclosure.

### DETAILED DESCRIPTION

Certain aspects of the present disclosure are generally directed to an electrically erasable programmable read-only memory (EEPROM) device comprising at least one EEPROM cell structure. Each EEPROM cell structure generally includes a first active region, a second active region, a channel region disposed between the first active region and the second active region, a floating gate structure disposed above the channel region and separated from the channel region by a first dielectric layer, and a control gate structure disposed above the floating gate structure and separated from the floating gate structure by a second dielectric layer. Additionally, to improve carrier injection into the floating gate, the EEPROM device also includes a bottom gate structure disposed below the channel region. For example, in some cases, the bottom gate structure may be biased to allow electric charge to be more easily injected into the floating gate structure when a pulsed voltage is applied to at least one of the first active region or the second active region.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

Certain terminology may also be used in the following description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

### Example EEPROM Device

As noted above, EEPROM devices are non-volatile memories that are able to retain their storage state after power is removed. Such non-volatility may be achieved through the use of a floating gate structure onto which electrical charge may be injected by a phenomenon known as “tunneling.” For example, a relatively high voltage (e.g., 15-20 volts) may be applied (e.g., pulsed) on a charge supply region of the EEPROM device, such as the drain or a region associated with the drain, creating a high electric field between the floating gate structure and the charge supply region. The high electric field allows electrons to jump or tunnel through a thin insulation material separating the floating gate structure from the charge supply region (known as “hot carrier injection”) without damage to the insulation separating the two regions. Similarly, by application of an opposite high voltage, charge may be removed from the floating gate, discharging the device.

Charge storage on the floating gate structure may be indicative of different logical states (e.g., a one or zero) and may be read by observing the threshold voltage at which the transistor containing the floating gate structure begins to conduct. A first threshold voltage indicates a positive charge storage on the floating gate structure, while a second threshold voltage indicates a negative charge storage.

However, as noted above, in order to inject or remove charge from the floating gate structure, a large programming voltage may be pulsed on the charge supply region. Aspects of the present disclosure provide an EEPROM device including a bottom gate structure that may be used to enhance hot carrier injection into the floating gate structure. For example, as described herein, aspects of the present disclosure provide a bottom gate structure that may allow for hot carrier injection using a reduced programming voltage.

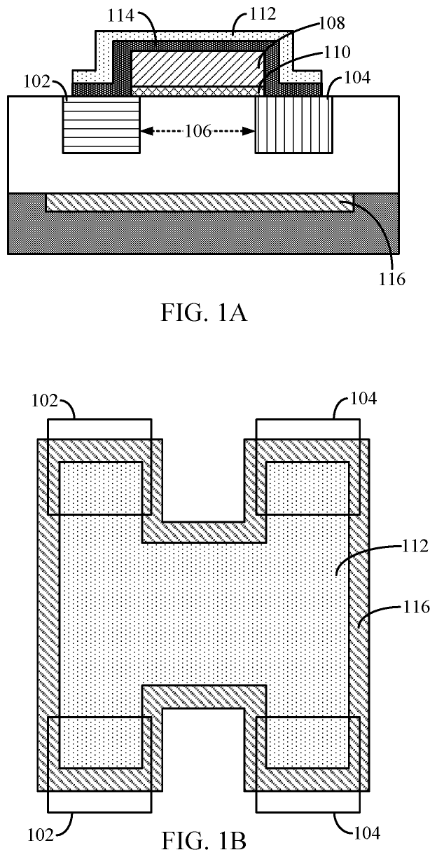

FIGS. 1A and 1B illustrate a cross-sectional frontal view and top view, respectively, of an electrically erasable programmable read-only memory (EEPROM) cell structure 100, in accordance with certain aspects presented herein.

As shown, the EEPROM cell structure 100 includes a first active region 102, a second active region 104, a channel region 106 disposed between the first active region 102 and the second active region 104. In traditional EEPROM devices, the first active region 102 and the second active region 104 may both comprise the same type of dopant. For example, in some cases, the first active region 102 and the second active region 104 may both comprise an N-doped material. In other cases, the first active region 102 and the second active region 104 may both comprise a P-doped material.

However, in other cases, the first active region 102 and the second active region 104 may comprise complementary-doped materials. For example, in some cases, the first active region 102 may comprise a P-doped material (e.g., P+) while the second active region 104 may comprise an N-doped material (e.g., N+) or vice versa. Complementary doped active regions may improve respective programing and erase functions associated with the EEPROM cell structure 100.

Further, as illustrated, the EEPROM cell structure 100 may include a floating gate structure 108 disposed above the channel region 106 and separated from the channel region 106 by a first dielectric layer 110. As noted above, the floating gate structure 108 may be used to store an amount of charge, representing data.

Further, as illustrated, the EEPROM cell structure 100 may include a control gate structure 112 disposed above the floating gate structure 108 and separated from the floating gate structure 108 by a second dielectric layer 114. The control gate structure 112 may be used to control a current flow between the first active region 102 and the second active region 104. Additionally, as described below, the control gate structure 112 may be used in a read operation of the EEPROM cell structure 100 (e.g., for reading data or charge stored in the floating gate structure 108).

In some cases, first dielectric layer 110 and the second dielectric layer 114 may be composed of an oxide material. Additionally, in some cases, the first dielectric layer 110 may be relatively thin to allow for electrons to “tunnel” between the floating gate structure 108 and at least one of the first active region 102 or the second active region 104.

Further, as noted above, the EEPROM cell structure 100 includes a bottom gate structure 116 disposed below the channel region 106. In some cases, for example, as illustrated, the bottom gate structure 116 comprises a plate structure. Additionally, in some cases, as illustrated, the bottom gate structure 116 has a larger area than the control gate structure 112. For example, the bottom gate structure 116 may be a proportionately larger structure (e.g., a scaled version) of the control gate structure 112. Additionally, in some cases, as illustrated, the bottom gate structure 116 has the same shape (e.g., an “H” shape”) as the control gate structure 112.

According to aspects, in some cases, the bottom gate structure 116 may be composed primarily of metal, such as copper. In other cases, the bottom gate structure 116 may be composed primarily of a semiconductor material, such as polycrystalline silicon.

As noted above, the EEPROM cell structure 100 may be used to store different logical states (e.g., bits of data) within the floating gate structure 108. In certain cases, to accomplish storage of these logical states, a process known as hot carrier injection may be used. As noted above, hot carrier injection may involve applying (pulsing) a relatively high programming voltage (e.g., 15-20 volts) on a charge supply region of the EEPROM device, such as the first active region 102 or the second active region 104, creating a high electric field between the floating gate structure 108 and the charge supply region. The high electric field allows electric charge carriers (e.g., holes or electrons) to jump or tunnel through a thin insulation material, such as the first dielectric layer 110, separating the floating gate structure 108 from the charge supply region.

For example, with reference to FIG. 1A, hot carrier injection, occurring during a write operation of the EEPROM cell structure 100, may involve pulsing a high programming voltage on the second active region 104. The high programming voltage allows a high electric field to develop in the channel region 106, which allows electric charge carriers, such as holes or electrons (e.g., depending on the polarity of the pulsed high programming voltage) to tunnel through the first dielectric layer 110 and become lodged in the floating gate structure 108. By injecting different amounts of electric charge, different logical states (e.g., data) may be developed/stored within the floating gate structure 108.

Aspects of the present disclosure provide techniques for enhancing hot carrier injection. For example, as described herein, to enhance hot carrier injection (e.g., charge injection into the floating gate structure 108), the EEPROM cell structure 100 may further include a bottom gate structure 116. In some cases, the bottom gate structure 116 may comprise a plate structure, such as an H-shaped plate structure as illustrated in FIGS. 1A and 1B. Additionally, in some cases, the bottom gate structure 116 may comprise primarily metal, such as copper. In other cases, the bottom gate structure 116 may comprise a semiconductor material, such as polycrystalline silicon. Additionally, in some cases, as illustrated, the bottom gate structure 116 may have a larger planar area than the control gate structure 112. In some cases, the bottom gate structure 116 may have a same shape as the control gate structure 112.

Further, in some cases, the bottom gate structure 116 may be configured to bias the channel region 106 during a write operation to lower a carrier injection threshold (e.g., a programming voltage level for inducing charge to tunnel into the floating gate structure 108). For example, when the bottom gate structure 116 is biased, an electric field may be developed within the channel region 106 that may enhance the speed of the electric charge being pulsed (e.g., via the pulsed programming voltage) on the second active region 104 (e.g., N+ doped region), allowing the electric charge to more easily tunnel through the first dielectric layer 110 at lower programming voltage levels (i.e., hot carrier injection thresholds). In certain cases, the bottom gate structure 116 may be biased by applying a more positive voltage than the pulsed programming voltage to enhance hot-carrier injection between the floating gate structure and the channel region.

For example, in some cases, the floating gate structure 108 may be programmed with a relatively large positive or a relatively large negative voltage such that considerable charge is injected and only two post-programming conditions are available (e.g., binary logic), storing a single bit of data. That is, a relatively large pulsed programming voltage may be applied to the second active region 104 such that the EEPROM cell structure is operable between two voltage levels and a single bit is stored in the EEPROM cell structure.

This bit of data or electric charge stored within the floating gate structure 108 may affect a threshold voltage (Vₜₕ) of the EEPROM cell structure 100, a voltage at which current may begin to flow through the channel region 106. Thus, the data stored in the floating gate structure 108 may be read by applying a voltage greater than Vth to the control gate structure 112 and measuring a current flowing from the first active region 102 (e.g., a P+ doped region).

In other cases, the bottom gate structure 116 may allow the electric charge injected into the floating gate structure 108 to be fine-tuned, leading to the ability to represent more than two logic states within the floating gate structure 108. For example, in some cases, an amount of charge stored in the floating gate structure 108 (e.g., representing different logic states) may be modified by applying the pulsed programming voltage to the second active region 104 at different levels or different polarities. For example, in some cases, a first pulsed programming voltage may inject a first amount of electric charge in the floating gate structure 108, corresponding to a first logic state, while a second pulsed programming voltage may inject a second amount of electric charge in the floating gate structure 108, corresponding to a second logic state. The amount of charge stored within the floating gate structure 108 may be modified by increasing the pulsed programming voltage, thereby injecting even more electric charge into the floating gate structure 108, increasing the threshold voltage, Vth, of the EEPROM cell structure 100 and leading to a lower read current. However, reversing a polarity of the pulsed programming voltage and injecting charge of an opposite polarity (e.g., negative polarity) into the floating gate structure 108 may reduce the amount of electric charge stored in the floating gate structure 108, lowering the Vth of the EEPROM cell structure 100 and increasing the read current. In some cases, the pulsed programming voltage can be positive with respect to ground to increase the positive charge on the gate, or negative with respect to ground to reduce the positive charge on the gate.

In some cases, the floating gate structure 108 may be used in a discrete manner where multiple logic states correspond to a bit pattern. For example, four different logic states, represented by four different amounts of electric charge, could correspond to two bits of data. In other cases, the floating gate structure 108 may be used in a continuous manner as an analog memory component where the stored value is increased or decreased by injection of positive or negative charge. This type of analog memory component may be useful, for example, in a neural network where the weighting of a given path is changed according to its relative importance.

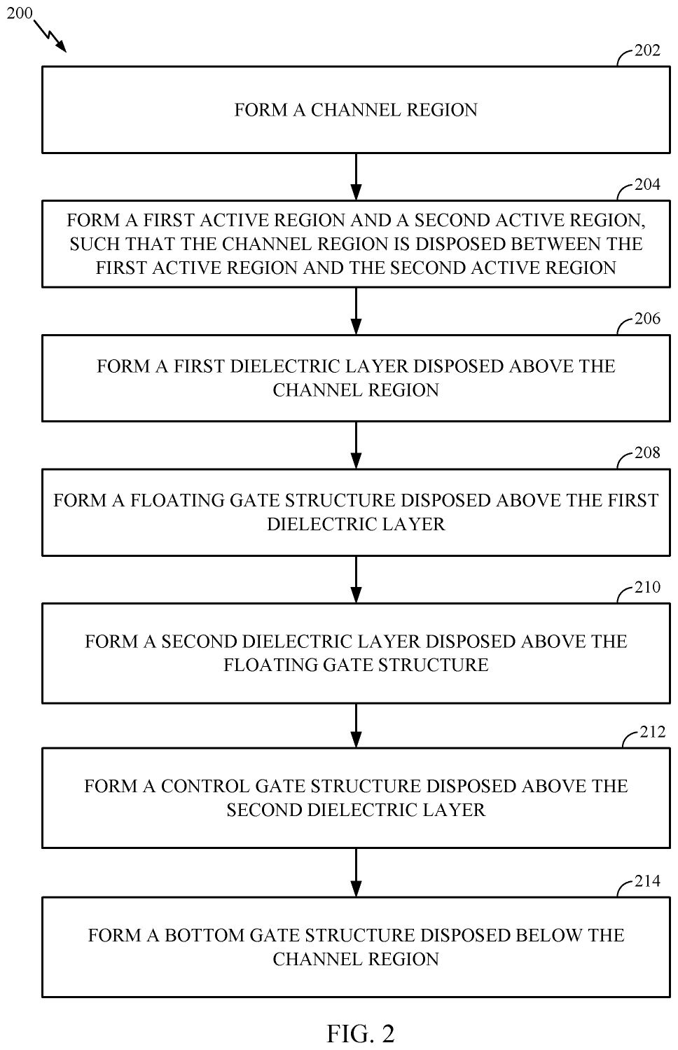

FIG. 2 is a flow diagram illustrating example operations 200 for fabricating an electrically erasable programmable read-only memory (EEPROM) device comprising at least one EEPROM cell structure, in accordance with certain aspects of the present disclosure. The operations 200 may be performed, for example, by a semiconductor processing facility.

The operations 200 begin, at block 202, with the semiconductor processing facility forming a channel region (e.g., channel region 106).

At block 204, the semiconductor processing facility forms a first active region (e.g., first active region 102) and a second active region (e.g., second active region 104), such that the channel region is disposed between the first active region and the second active region. Formation of the first active region and/or the second active region may be accomplished, for example, by doping end portions of the channel region. In some cases, the first active region comprises a P-doped material and the second active region comprises an N-doped material.

At block 206, the semiconductor processing facility forms a first dielectric layer (e.g., first dielectric layer 110) disposed above the channel region. In some cases, the first dielectric layer is composed of an oxide material.

At block 208, the semiconductor processing facility forms a floating gate structure (e.g., floating gate structure 108) disposed above the first dielectric layer.

At block 210, the semiconductor processing facility forms a second dielectric layer (e.g., second dielectric layer 114) disposed above the floating gate structure. In some cases, the second dielectric layer is composed of an oxide material.

At block 212, the semiconductor processing facility forms a control gate structure (e.g., control gate structure 112) disposed above the second dielectric layer.

At block 214, the semiconductor processing facility forms a bottom gate structure (e.g., bottom gate structure 116) disposed below the channel region. In some cases, the bottom gate structure comprises a plate structure. Further, in some cases, the bottom gate structure is composed primarily of metal. In some cases, the metal comprises copper. In other cases, the bottom gate structure is composed primarily of a semiconductor material. For example, the semiconductor material may be polycrystalline silicon. The bottom gate structure may be configured to bias the channel region during a write operation to lower a carrier injection threshold.

In some cases, the bottom gate structure has a larger area than the control gate structure. Additionally, in some cases, the bottom gate structure has the same shape as the control gate structure.

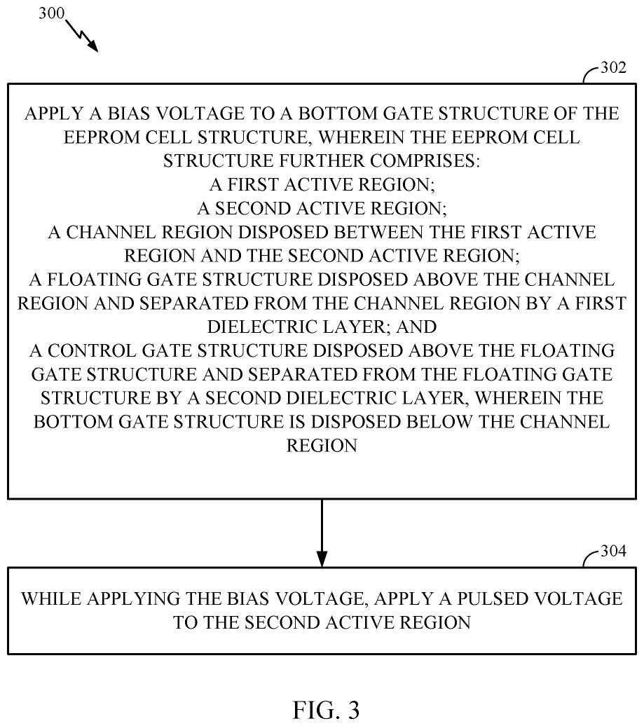

FIG. 3 is a flow diagram illustrating example operations 300 for operating an electrically erasable programmable read-only memory (EEPROM) cell structure, in accordance with certain aspects of the present disclosure. The operations 200 may be performed, for example, by a circuit (e.g., an integrated circuit (IC) or a system on a chip (SoC)) that includes an EEPROM device having at least one EEPROM cell.

The operations 300 begin, at block 302, with the circuit applying a bias voltage to a bottom gate structure of the EEPROM cell structure. The EEPROM cell structure further comprises: a first active region, a second active region, a channel region disposed between the first active region and the second active region, a floating gate structure disposed above the channel region and separated from the channel region by a first dielectric layer, and a control gate structure disposed above the floating gate structure and separated from the floating gate structure by a second dielectric layer. The bottom gate structure is disposed below the channel region. While applying the bias voltage at block 302, the circuit applies a pulsed voltage to the second active region at block 304.

In some cases, the first active region comprises a P-doped material, and the second active region comprises an N-doped material.

In some cases, applying the pulsed voltage to the second active region modifies an amount of charge stored in the floating gate structure.

In some cases, applying the bias voltage to the bottom gate structure comprises applying a more positive voltage than the pulsed voltage to enhance hot-carrier injection between the floating gate structure and the channel region.

Additionally, in some cases, applying the pulsed voltage comprises applying a relatively large pulsed voltage to the second active region such that the EEPROM cell structure is operable between two voltage levels and a single bit is stored in the EEPROM cell structure.

Additionally, in some cases, applying the pulsed voltage comprises applying one or more relatively small pulsed voltages to the second active region such that the EEPROM cell structure is operable between more than two voltage levels and multiple bits are stored in the EEPROM cell structure.

Additionally, in some cases, operating the EPPROM cell structure further comprises reading a state of the EEPROM cell structure by measuring a current from the first active region.

Additionally, in some cases, the bottom gate structure comprises a larger area than the control gate structure.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

1. An electrically erasable programmable read-only memory (EEPROM) device comprising at least one EEPROM cell structure comprising:
a first active region;
a second active region;
a channel region disposed between the first active region and the second active region;
a floating gate structure disposed above the channel region and separated from the channel region by a first dielectric layer;
a control gate structure disposed above the floating gate structure and separated from the floating gate structure by a second dielectric layer; and
a bottom gate structure disposed below the channel region.

2. The EEPROM device of claim 1, wherein:
the first active region comprises a P-doped material; and
the second active region comprises an N-doped material.

3. The EEPROM device of claim 1, wherein the bottom gate structure comprises a plate structure.

4. The EEPROM device of claim 1, wherein the bottom gate structure is composed primarily of metal.

5. The EEPROM device of claim 4, wherein the metal comprises copper.

6. The EEPROM device of claim 1, wherein the bottom gate structure is composed primarily of a semiconductor material.

7. The EEPROM device of claim 6, wherein the semiconductor material comprises polycrystalline silicon.

8. The EEPROM device of claim 1, wherein the bottom gate structure is configured to bias the channel region during a write operation to lower a carrier injection threshold.

9. The EEPROM device of claim 1, wherein the bottom gate structure has a larger area than the control gate structure.

10. The EEPROM device of claim 1, wherein the bottom gate structure has a same shape as the control gate structure.

11. The EEPROM device of claim 1, wherein the first dielectric layer and the second dielectric layer are composed of an oxide material.

12. A method of operating an electrically erasable programmable read-only memory (EEPROM) cell structure, the method comprising:
applying a bias voltage to a bottom gate structure of the EEPROM cell structure, wherein the EEPROM cell structure further comprises:
a first active region;
a second active region;
a channel region disposed between the first active region and the second active region;
a floating gate structure disposed above the channel region and separated from the channel region by a first dielectric layer; and
a control gate structure disposed above the floating gate structure and separated from the floating gate structure by a second dielectric layer, wherein the bottom gate structure is disposed below the channel region; and
while applying the bias voltage, applying a pulsed voltage to the second active region.

13. The method of claim 12, wherein:
the first active region comprises a P-doped material; and
the second active region comprises an N-doped material.

14. The method of claim 12, wherein applying the pulsed voltage to the second active region modifies an amount of charge stored in the floating gate structure.

15. The method of claim 12, wherein applying the bias voltage to the bottom gate structure comprises applying a more positive voltage than the pulsed voltage to enhance hot-carrier injection between the floating gate structure and the channel region.

16. The method of claim 12, wherein applying the pulsed voltage comprises applying a relatively large pulsed voltage to the second active region such that the EEPROM cell structure is operable between two voltage levels and a single bit is stored in the EEPROM cell structure.

17. The method of claim 12, wherein applying the pulsed voltage comprises applying one or more relatively small pulsed voltages to the second active region such that the EEPROM cell structure is operable between more than two voltage levels and multiple bits are stored in the EEPROM cell structure.

18. The method of claim 12, further comprising reading a state of the EEPROM cell structure by measuring a current from the first active region.

19. The method of claim 12, wherein the bottom gate structure comprises a larger area than the control gate structure.

20. A method of fabricating an electrically erasable programmable read-only memory (EEPROM) device comprising at least one EEPROM cell structure, the method comprising:
forming a channel region;
forming a first active region and a second active region, such that the channel region is disposed between the first active region and the second active region;
forming a first dielectric layer disposed above the channel region;
forming a floating gate structure disposed above the first dielectric layer;
forming a second dielectric layer disposed above the floating gate structure;
forming a control gate structure disposed above the second dielectric layer; and
forming a bottom gate structure disposed below the channel region.

21. (canceled)

22. (canceled)
